(19) United States
(12) Patent Application Publication
(10) Pub. No.: US 2005/0227469 A1
(43) Pub. Date: Oct. 13, 2005

(54) Method of manufacturing semiconductor device

(75) Inventors: Sung-hyung Park, Chungcheongbuk-do (KR); Hi-deok Lee, Daejeon-Si (KR)

Correspondence Address: MARSHALL, GERSTEIN & BORUN LLP, 233 S. WACKER DRIVE, SUITE 6300, SEARS TOWER, CHICAGO, IL, 60606, US

(73) Assignee: Magnachip Semiconductor, Ltd., Chungcheongbuk-do (KR)

(21) Appl. No.: 10/990,922

(22) Filed: Nov. 17, 2004

(30) Foreign Application Priority Data
Apr. 9, 2004 (KR) 2004-24597

(51) Int. Cl. H01L 21/3205

(52) U.S. Cl. 438/592

(57) ABSTRACT

Disclosed herein is a method of manufacturing a semiconductor device. The method comprises the steps of a) depositing nickel and cobalt layers sequentially on a silicone substrate having a transistor formed thereon, b) forming a silicide layer from the nickel and cobalt layers deposited on the silicone substrate by a rapid thermal process, and c) annealing and wet-etching the semiconductor device obtained in the step b). As the double layers of nickel/cobalt are formed, a resistance difference between N-polysilicone and P-polysilicone is lowered, and thermal stability during a subsequent heat treatment process after forming the silicide is enhanced.

### BACKGROUND OF THE INVENTION

1. Field of the Invention

The present invention relates to a method of manufacturing a semiconductor device, and more particularly to a method of manufacturing a semiconductor device, which forms double layers of nickel/cobalt (Ni/Co) instead of double layers of cobalt/nickel (Co/Ni) used in the existing semiconductor device, thereby reducing a resistance difference between N-polysilicone and P-polysilicone, and ensuring an enhanced thermal stability during a heat treatment.

2. Description of the Related Art

In general, a silicide process means a process for forming a reactant compound with silicone through a heat treatment after depositing metals, such as cobalt, nickel, titanium and the like, on a silicone substrate.

Due to a recent trend of deep-submicron design in the field of semiconductor device, a line-width is decreased, causing a frequent cohesion phenomenon, wherein the lines of a silicide cohere and are then cut off during a subsequent heat treatment process.

Particularly, in nano-scale semiconductors of the near future, due to a short channel effect caused by shortening of a gate length, a shallow junction must be applied to the semiconductor. In the shallow junction, there is a need to provide nickel silicide, which consumes a smaller amount of nickel than cobalt silicide when forming the silicide.

Thus a continuing trend in current logic technology of 0.13 μm or less is to replace cobalt silicide with nickel silicide for enhancing the short channel effect. Nickel silicide is expanding its application toward a nano-CMOS (complementary Metal Oxide Semiconductor) due to its advantages in that nickel silicide has a constant sheet resistance according to a line-width in a fine line-width less than 0.10 μm as well as a low silicone consumption rate and a low specific resistance.

However, nickel silicide exhibits very weak thermal characteristics for the heat treatment process after forming the silicide.

That is, grains of nickel silicide are locally recombined to form a large grain by the subsequent heat treatment process, causing the cohesion phenomenon wherein uniformity of the grains are deteriorated and the lines are cut off.

Thus, a conventional method forms the silicide with an application of double layers of cobalt/nickel to solve this problem. That is, although the existing nickel silicide coheres as nickel di-silicide transformed from nickel mono-silicide by the subsequent heat treatment process, when forming the silicide by addition of cobalt, nickel di-silicide can be suppressed, and even though nickel di-silicide is formed, cobalt di-silicide acts to lower total resistance.

However, when cobalt is deposited earlier than nickel, cobalt silicide is formed earlier than nickel silicide, leading to a large consumption of silicone, which occurs in particular at poly silicone layers, thereby causing a problem of resistance difference between N-polysilicone and P-polysilicone.

FIG. 1 is a graphical representation depicting a large resistance difference between the polysilicone, when using the conventional double layers of cobalt/nickel as described above.

As shown in FIG. 1, when using the conventional double layers of cobalt/nickel, there is a problem of large resistance difference between the polysilicone.

Further, FIG. 2 is a graphical representation depicting an unstable thermal characteristic of an N-active layer formed by the conventional double layers of cobalt/nickel as described above.

As shown in FIG. 2, when using the conventional double layers of cobalt/nickel, a sheet resistance of the N-active layer is not detected due to abnormal oxidation, thereby causing a problem in that the thermal characteristic of the N-active layer is unstable in the cobalt/nickel structure.

### SUMMARY OF THE INVENTION

The present invention has been made to solve the above problems, and it is an object of the present invention to provide a method of manufacturing a semiconductor device, which forms double layers of nickel/cobalt (Ni/Co) instead of double layers of cobalt/nickel used in the existing semiconductor device, thereby reducing a resistance difference between N-poly and P-poly, and ensuring an enhanced thermal stability during a heat treatment.

In accordance with one aspect of the present invention, the above and other objects can be accomplished by the provision of a method of manufacturing a semiconductor device, comprising the steps of: a) depositing nickel and cobalt layers sequentially on a silicone substrate having a transistor formed thereon; b) forming a silicide layer from the deposited nickel and cobalt layers on the silicone substrate by a rapid thermal process (RTP); and c) annealing and wet-etching in the step b).

The nickel may be deposited to a thickness of 100 Å at the same temperature as that of the silicone substrate under conditions of a vacuum pressure of 1 mTorr and a substrate distance of 15 cm.

The cobalt may be deposited to a thickness of 10 Å at the same temperature as that of the silicone substrate under conditions of a vacuum pressure of 1 mTorr and a substrate distance of 15 cm.

The RTP may be carried out at a temperature of 500˜700° C. for 30 seconds, 60 seconds or 90 seconds.

The annealing process may be carried out at a temperature of 650 or 700° C. for 30 minutes.

The wet etching process may be carried out for 15 minutes using a mixture of H₂SO₄ and H₂O₂ in a ratio of 4:1.

According to the method of the present invention, there are provided advantageous effects in that double layers of nickel/cobalt are formed, thereby lowering a resistance difference between N-polysilicone and P-polysilicone, reducing consumption of silicone for a shallow junction, and enhancing thermal stability during a subsequent heat treatment process after forming the silicide.

### BRIEF DESCRIPTION OF THE DRAWINGS

The foregoing and other objects and features of the present invention will be more clearly understood from the following detailed description taken in conjunction with the accompanying drawings, in which:

FIG. 1 is a graphical representation depicting a resistance difference between poly silicone layers formed of conventional double layers of cobalt/nickel;

FIG. 2 is a graphical representation depicting an unstable thermal characteristic of an N-active layer formed of the conventional double layers of cobalt/nickel;

FIGS. 3a to 3c are cross sections showing steps for manufacturing a semiconductor device according to the present invention;

FIG. 4 is a graphical representation depicting a resistance difference between poly silicone layers when using double layers of nickel/cobalt according to the present invention; and

FIG. 5 is a graphical representation depicting a stable thermal characteristic of an N-active layer when using the double layers of nickel/cobalt according to the present invention.

### DESCRIPTION OF THE PREFERRED EMBODIMENTS

Preferred embodiments will now be described in detail with reference to the accompanying drawings. These embodiments are provided for the purpose of illustration, and it should be not considered that the scope of the invention is limited by the embodiments.

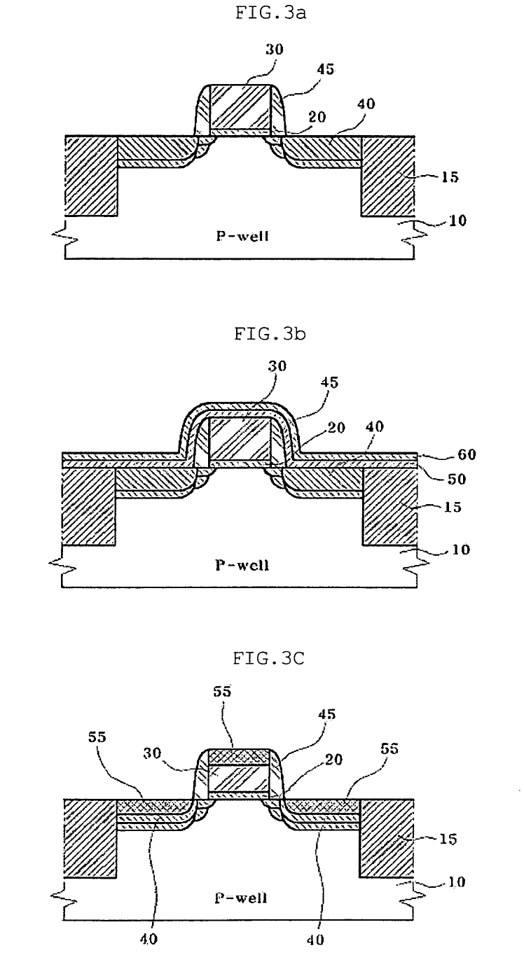

FIGS. 3a to 3c are cross sections showing steps for manufacturing a semiconductor device according to the present invention.

First, as shown in FIG. 3a, a gate consisting of a gate oxide film 20 and a poly-silicone 30 is formed on a silicone substrate 10, which is formed with a device separating film 15 and defined with a P-well, and spacers 45 of a dielectric film are then formed at both sides of the gate. Then, impurities are injected into the silicone substrate 10 at lower portions of both sides of the gate, forming source/drain regions 40 to provide a transistor.

Then, as shown in FIG. 3b, a nickel layer 50 and a cobalt layer 60 are sequentially deposited on the transistor such that the nickel layer 50 and the cobalt layer 60 have a thickness of 100 Å and 10 Å, respectively.

Further, preferably, the nickel layer 50 and the cobalt layer 60 are deposited at the same temperature as that of the silicone substrate under conditions of a base pressure of 3E−7 Torr, a vacuum pressure of 1 mTorr, and a substrate distance of 15 cm between a deposition source (not shown) and the silicone substrate.

Then, the nickel and cobalt layers 50 and 60 deposited on the substrate are heat treated at a temperature of 550° C. for 60 seconds with a rapid thermal process (RTP), forming a silicide layer.

Then, as shown in FIG. 3c, the silicide layer 55 is formed through a selective reaction of the nickel and cobalt layers 50 and 60 where silicone is present.

Here, preferably, the RTP heat treatment is carried out at a temperature of 500˜700° C. for 30 seconds, 60 seconds or 90 seconds.

Then, an annealing process is carried out to the silicide layer 55 on the substrate to evaluate thermal stability, and then a wet-etching process is carried out to remove a remaining residue.

Here, the annealing process may be carried out at a temperature of 650 or 700° C. for 30 minutes, and the wet etching process may be carried out for 15 minutes using a mixture of H₂SO₄ and H₂O₂ in a ratio of 4:1.

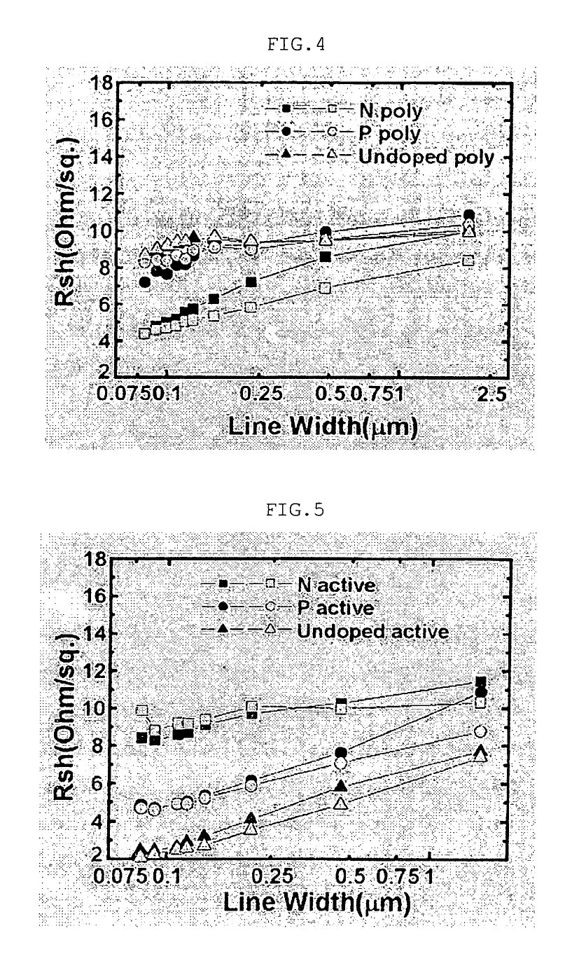

FIG. 4 is a graphical representation showing that a sheet resistance difference between poly silicone layers is reduced, as the double layers of nickel/cobalt of the present invention as described above are used.

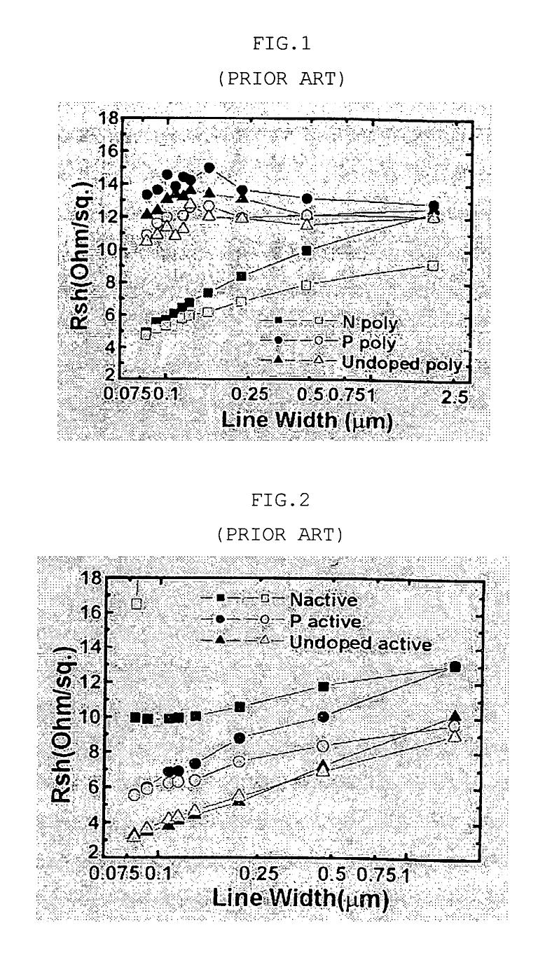

Referring to FIG. 4, when using the double layers of nickel/cobalt according to the present invention, the sheet resistance between the N-polysilicone and P-polysilicone is remarkably reduced, compared with FIG. 1, and the resistance after the heat treatment is scaresely increased, compared with the resistance before the heat treatment.

That is, in the present invention, nickel is deposited earlier than cobalt, forming nickel silicide earlier than cobalt silicide, so that the consumption of silicon is relatively reduced.

Further, FIG. 5 is a graphical representation showing that a stable thermal characteristic of an N-active layer is achieved when using the double layers of nickel/cobalt of the present invention as described above.

As shown in FIG. 5, compared with the conventional double layer of nickel/cobalt in which the sheet resistance of the N-active layer is not detected as shown in FIG. 2, when using the double layers of nickel/cobalt according to the present invention, the sheet resistance of the N-active layer is detected after the heat treatment, so that the thermal stability is provided.

That is, the present invention enables a low sheet resistance to be maintained by an additional deposition of Co layer on the existing nickel silicide, using characteristics of cobalt silicide that when cobalt silicide is transformed into di-silicide after the heat treatment at high temperature, the thermal stability can be achieved due to a low sheet resistance of a CoSi₂ (di-silicide) phase.

Further, as for a new phase caused by a combination of nickel/cobalt and silicone, a triple phase of (Ni₁₋ₓCoₓ)Si₂ is formed, instead of a NiSi₂(di-silicide) phase having a high sheet resistance, thereby maintaining the low sheet resistance and the thermal stability.

As apparent from the above description, according to the present invention, the double layers of nickel/cobalt are formed, thereby lowering the resistance difference between the N-polysilicone and the P-polysilicone, reducing the consumption amount of silicone for a shallow junction, and enhancing the thermal stability of a subsequent heat treatment process after forming the silicide.

It should be understood that the embodiments and the accompanying drawings as described above have been described for illustrative purposes and the present invention is limited only by the following claims. Further, those skilled in the art will appreciate that various modifications, additions and substitutions are allowed without departing from the scope and spirit of the invention as set forth in the accompanying claims.

1. A method of manufacturing a semiconductor device, comprising the steps of:
a) depositing nickel and cobalt layers sequentially on a silicone substrate having a transistor formed thereon;
b) forming a silicide layer from the nickel and cobalt layers deposited on the silicone substrate by a rapid thermal process (RTP); and
c) annealing and wet etching.

2. The method as set froth in claim 1, wherein the nickel is deposited to a thickness of 100 Å at the same temperature as that of the silicone substrate under conditions of a vacuum pressure of 1 mTorr and a substrate distance of 15 cm.

3. The method as set froth in claim 1, wherein the cobalt is deposited to a thickness of 10 Å at the same temperature as that of the silicone substrate under conditions of a vacuum pressure of 1 mTorr and a substrate distance of 15 cm.

4. The method as set froth in claim 1, wherein the RTP heat treatment is carried out at a temperature of 500˜700° C. for 30 seconds, 60 seconds or 90 seconds.

5. The method as set froth in claim 1, wherein the annealing process is carried out at a temperature of 650 or 700° C. for 30 minutes.

6. The method as set froth in claim 1, wherein the wet etching process is carried out for 15 minutes using a mixture of H₂SO₄ and H₂O₂ in a ratio of 4:1.
